(19) United States
(12) Patent Application Publication
(10) Pub. No.: US 2026/0068733 A1
(43) Pub. Date: Mar. 5, 2026

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Changbo LEE, Suwon-si (KR); PIL-KYU KANG, Suwon-si (KR); JAE-WHA PARK, Suwon-si (KR)

(73) Assignee: SAMSUNG ELECTRONICS CO., LTD., Suwon-si (KR)

(21) Appl. No.: 19/085,551

(22) Filed: Mar. 20, 2025

(30) Foreign Application Priority Data
Aug. 30, 2024 (KR) 10-2024-0117448

(51) Int. Cl. H01L 23/00

(52) U.S. Cl. CPC H01L 24/08

(57) ABSTRACT

A semiconductor device includes a first semiconductor chip having a first surface and a second surface that is opposite to the first surface, a second semiconductor chip having a third surface facing the first surface and a fourth surface that is opposite to the third surface, a first dielectric layer on the first surface of the first semiconductor chip, a second dielectric layer on the third surface of the second semiconductor chip, a connection pad including a first conductive pad penetrating the first dielectric layer and a second conductive pad penetrating the second dielectric layer, and an adhesive layer between the first dielectric layer and the second dielectric layer, where the adhesive layer includes an organic dielectric material, the first conductive pad and the second conductive pad extend into the adhesive layer, and the first conductive pad directly contacts the second conductive pad.

### CROSS-REFERENCE TO RELATED APPLICATION

This application is based on and claims priority to Korean Patent Application No. 10-2024-0117448, filed on Aug. 30, 2024, in the Korean Intellectual Property Office, the disclosure of which is incorporated by reference herein in its entirety.

### BACKGROUND

The present disclosure relates to a semiconductor device and a method of fabricating the same, and more particularly, to a semiconductor device including a plurality of bonded semiconductor chips and a method of fabricating the same.

A semiconductor package is provided to implement an integrated circuit chip for use in electronic products. Typically, in the semiconductor package, a semiconductor chip is mounted on a printed circuit board (PCB) and bonding wires or bumps are used to electrically connect the semiconductor chip to the PCB. With the development of the electronic industry, there is a demand for smaller, lighter, and multifunctional electronic devices.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device that may be capable of easily bonding a plurality of semiconductor chips and a method of fabricating the same.

Additional aspects will be set forth in part in the description which follows and, in part, will be apparent from the description, or may be learned by practice of the presented embodiments.

According to an aspect of an example embodiment, a semiconductor device may include a first semiconductor chip having a first surface and a second surface that is opposite to the first surface, a second semiconductor chip having a third surface facing the first surface and a fourth surface that is opposite to the third surface, a first dielectric layer on the first surface of the first semiconductor chip, a second dielectric layer on the third surface of the second semiconductor chip, a connection pad including a first conductive pad penetrating the first dielectric layer and a second conductive pad penetrating the second dielectric layer, and an adhesive layer between the first dielectric layer and the second dielectric layer, where the adhesive layer includes an organic dielectric material, the first conductive pad and the second conductive pad extend into the adhesive layer, and the first conductive pad directly contacts the second conductive pad.

According to an aspect of an example embodiment, a semiconductor device may include a first semiconductor chip having a first surface and a second surface that is opposite to the first surface, a second semiconductor chip having a third surface facing the first surface and a fourth surface that is opposite to the third surface, a connection pad including a first conductive pad and a second conductive pad, and an adhesive layer between the first surface of the first semiconductor chip and the third surface of the second semiconductor chip, where the adhesive layer includes an organic dielectric material, the first conductive pad extends from the first surface into the adhesive layer, the second conductive pad extends from the third surface into the adhesive layer, and the first conductive pad contacts the second conductive pad.

According to an aspect of an example embodiment, a semiconductor device may include a first semiconductor chip having a first surface and a second surface that is opposite to the first surface, a second semiconductor chip having a third surface facing the first surface and a fourth surface that is opposite to the third surface, a plurality of connection pads spaced apart from each other in a first direction parallel to the first surface, each of the plurality of connection pads including a first conductive pad and a second conductive pad directly contacting the first conductive pad, a first dielectric layer on the first surface and between the first conductive pads of the plurality of connection pads, a second dielectric layer on the third surface and between the second conductive pads of the plurality of connection pads, and an adhesive layer between the first dielectric layer and the second dielectric layer, where the adhesive layer includes an organic dielectric material, and the first conductive pads and the second conductive pads of the plurality of connection pads extend into the adhesive layer.

### BRIEF DESCRIPTION OF DRAWINGS

The above and other aspects, features, and advantages of certain example embodiments of the present disclosure will be more apparent from the following description taken in conjunction with the accompanying drawings, in which

FIG. 1 is a cross-sectional view illustrating a semiconductor device according to one or more embodiments;

FIGS. 2A, 2B, and 2C are enlarged cross-sectional views illustrating examples of section P1 of FIG. 1 according to one or more embodiments;

FIGS. 3 to 8 are cross-sectional views illustrating a method of fabricating a semiconductor device according to one or more embodiments;

FIG. 9 is a cross-sectional view illustrating a semiconductor device according to one or more embodiments;

FIG. 10 is an enlarged cross-sectional view illustrating section P2 of FIG. 9 according to one or more embodiments;

FIGS. 11 to 16 are cross-sectional views illustrating a method of fabricating a semiconductor device according to one or more embodiments;

FIG. 17 is a cross-sectional view illustrating a semiconductor device according to one or more embodiments; and

FIG. 18 is a cross-sectional view illustrating a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

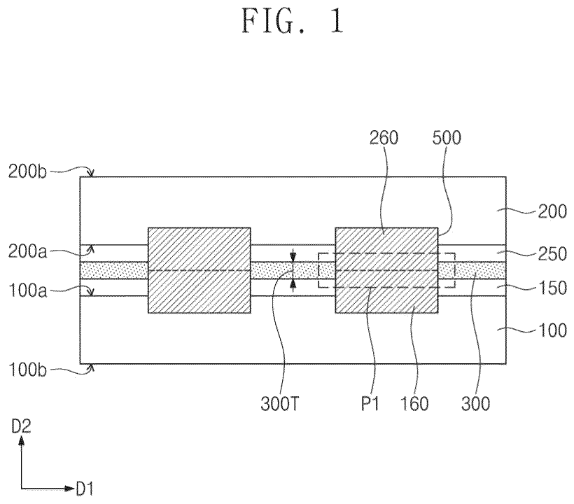

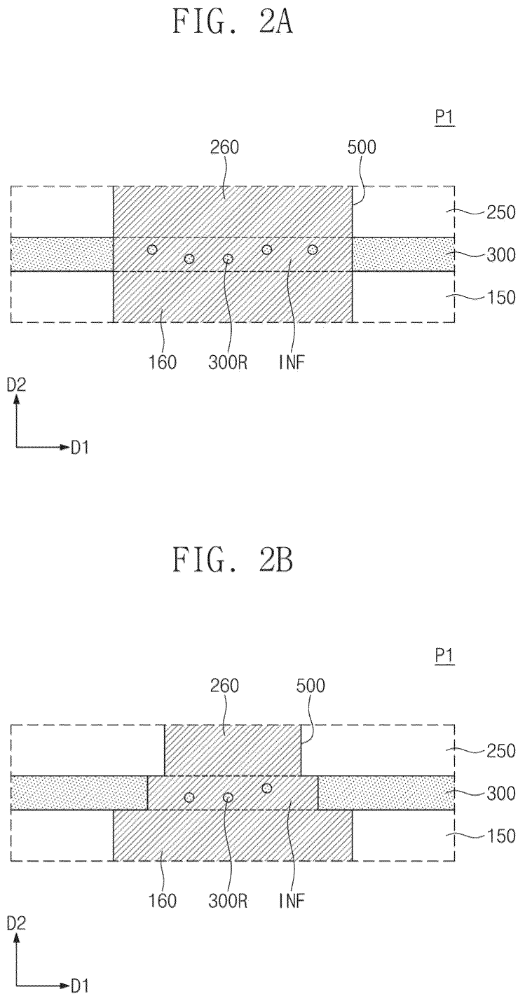

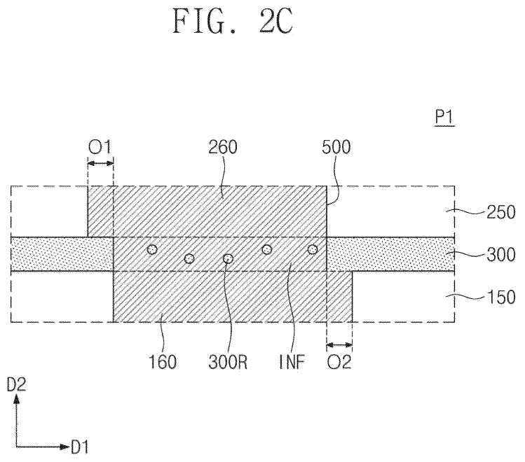

FIG. 1 is a cross-sectional view illustrating a semiconductor device according to one or more embodiments. FIGS. 2A, 2B, and 2C are enlarged cross-sectional views illustrating examples of section P1 of FIG. 1, according to one or more embodiments.

Referring to FIG. 1, a semiconductor device may include a first semiconductor chip 100, a second semiconductor chip 200 on the first semiconductor chip 100, a first dielectric layer 150 between the first semiconductor chip 100 and the second semiconductor chip 200, a second dielectric layer 250 between the first dielectric layer 150 and the second semiconductor chip 200, an adhesive layer 300 between the first dielectric layer 150 and the second dielectric layer 250, and a connection pad 500 that penetrates the first dielectric layer 150, the adhesive layer 300, and the second dielectric layer 250, and that electrically connects the first semiconductor chip 100 and the second semiconductor chip 200 to each other.

The first semiconductor chip 100 may have a first surface 100a and a second surface 100b that are opposite to each other. The first semiconductor chip 100 may include an integrated circuit therein, and for example, may be a memory chip, a logic chip, an application processor (AP) chip, a system-on-chip (SOC), etc. The second semiconductor chip 200 may have a third surface 200a and a fourth surface 200b that are opposite to each other. The third surface 200a of the second semiconductor chip 200 may face the first surface 100a of the first semiconductor chip 100. The second semiconductor chip 200 may include an integrated circuit therein, and for example, may be a memory chip, a logic chip, an AP chip, a SOC, etc. According to one or more embodiments, the first semiconductor chip 100 and the second semiconductor chip 200 may be the same semiconductor chip. According to one or more embodiments, the first semiconductor chip 100 and the second semiconductor chip 200 may be different semiconductor chips from each other.

The first dielectric layer 150 may be disposed between the first semiconductor chip 100 and the second semiconductor chip 200, and may be adjacent to the first surface 100a of the first semiconductor chip 100. The second dielectric layer 250 may be disposed between the first semiconductor chip 100 and the second semiconductor chip 200, and may be adjacent to the third surface 200a of the second semiconductor chip 200. Each of the first dielectric layer 150 and the second dielectric layer 250 may include a silicon-containing dielectric material, which silicon-containing dielectric material may include at least one of silicon oxide (SiO₂), silicon nitride (SiN), silicon oxynitride (SiON), silicon carbonitride (SiCN), and silicon carbon oxynitride (SiCON). The first dielectric layer 150 and the second dielectric layer 250 may include the same dielectric material.

The adhesive layer 300 may be disposed between and directly contact the first dielectric layer 150 and the second dielectric layer 250. The adhesive layer 300 may include an organic dielectric material, such as at least one of epoxy, polyvinyl alcohol (PVA), polyvinyl phenol (PVP), polymethylmethacrylate (PMMA), polyimide (PI), and polycarbonate (PC). The adhesive layer 300 may include at least one polymer of pyromellitic dianhydride-oxydianiline (PMDA-ODA), bisphenyldianhydride-phenyldiamine (BPDA-PDA), bisphenol-A polycarbonate (BPA-PC), and trimethylcyclohexane polycarbonate (TMC-PC).

The connection pad 500 may include a first conductive pad 160 that penetrates the first dielectric layer 150 and is adjacent to the first surface 100a of the first semiconductor chip 100, and may also include a second conductive pad 260 that penetrates the second dielectric layer 250 and is adjacent to the third surface 200a of the second semiconductor chip 200. The first conductive pad 160 may be electrically connected to the integrated circuit of the first semiconductor chip 100, and the second conductive pad 260 may be electrically connected to the integrated circuit of the second semiconductor chip 200. The first conductive pad 160 and the second conductive pad 260 may extend into the adhesive layer 300, and may directly contact each other to constitute the connection pad 500. The first conductive pad 160 and the second conductive pad 260 may contact each other without a boundary, and may constitute one body of the connection pad 500. The first semiconductor chip 100 and the second semiconductor chip 200 may be electrically connected to each other through the connection pad 500. Each of the first conductive pad 160 and the second conductive pad 260 may include metal, such as copper. The first conductive pad 160 and the second conductive pad 260 may include the same metal.

Referring to FIGS. 1, 2A, 2B, and 2C, the connection pad 500 may include an interface region INF that penetrates the adhesive layer 300. The interface region INF of the connection pad 500 may be substantially aligned with the adhesive layer 300 along a first direction D1. That is, the interface region INF may have the same height as the adhesive layer 300 and may extend along the first direction D1 at substantially the same vertical position and vertical height in the second direction D2. The first direction D1 may be parallel to the first surface 100a of the first semiconductor chip 100 and the third surface 200a of the second semiconductor chip 200. According to one or more embodiments, the connection pad 500 may include organic particles 300R provided in the interface region INF. The organic particles 300R may include the same material as that of the adhesive layer 300.

According to one or more embodiments, referring to FIG. 2A, a width in the first direction D1 of the first conductive pad 160 may be substantially the same as a width in the first direction D1 of the second conductive pad 260, and the first conductive pad 160 and the second conductive pad 260 may be vertically aligned with each other along a second direction D2. The second direction D2 may be perpendicular to the first surface 100a of the first semiconductor chip 100 and the third surface 200a of the second semiconductor chip 200.

According to one or more embodiments, referring to FIG. 2B, a width in the first direction D1 of the first conductive pad 160 may be different from a width in the first direction D1 of the second conductive pad 260. In this case, a width in the first direction D1 of the interface region INF in the connection pad 500 may fall within a range between a width in the first direction D1 of the first conductive pad 160 and a width in the first direction D1 of the second conductive pad 260. For example, a width in the first direction D1 of the first conductive pad 160 may be greater than a width in the first direction D1 of the second conductive pad 260. In this case, a width in the first direction D1 of the interface region INF in the connection pad 500 may be the same as or less than a width in the first direction D1 of the first conductive pad 160 and may be the same as or greater than a width in the first direction D1 of the second conductive pad 260.

According to one or more embodiments, referring to FIG. 2C, the first conductive pad 160 and the second conductive pad 260 may be partially aligned with each other along the second direction D2. For example, a portion of the first conductive pad 160 may be vertically aligned along the second direction D2 with a portion of the second conductive pad 260, and a remainder of the first conductive pad 160 may extend along the first direction D1 below the adhesive layer 300. A portion of the second conductive pad 260 may be vertically aligned along the second direction D2 with a portion of the first conductive pad 160, and a remainder of the second conductive pad 260 may extend along a direction opposite to the first direction D1 onto the adhesive layer 300. That is, the second conductive pad 260 may be horizontally offset from the first conductive pad 160 with respect to the direction D2. In particular, the second conductive pad 260 may be horizontally offset from the first conductive pad 160 by an offset distance O1, and the first conductive pad 160 may be horizontally offset from the second conductive pad 260 by an offset distance O2. As shown in FIG. 2C, since the widths of the first conductive pad 160 and the second conductive pad 260 are the same, the offset distances O1 and O2 are the same, but embodiments are not limited thereto. In one or more embodiments where the widths of the first conductive pad 160 and the second conductive pad 260 are different (e.g., FIG. 2B), the offset distances O1 and O2 may be different. In the case shown in FIG. 2C where the widths of the first conductive pad 160 and the second conductive pad 260 are the same, the width of the interface region INF may be substantially equal to the width of either the first conductive pad 160 and the second conductive pad 260 minus the offset distance O1 or O2. Various aspects of FIGS. 2A to 2C may be combined without departing from the scope of the disclosure as will be understood by one of ordinary skill in the art.

Referring back to FIG. 1, the adhesive layer 300 may have a thickness 300T in the second direction D2, and for example, the thickness 300T of the adhesive layer 300 may range from about 10 nm to about 100 nm.

A plurality of first conductive pads 160 may be provided. The plurality of first conductive pads 160 may be disposed adjacent to the first surface 100a of the first semiconductor chip 100 and spaced apart from each other in the first direction D1. A plurality of second conductive pads 260 may be provided. The plurality of second conductive pads 260 may be disposed adjacent to the third surface 200a of the second semiconductor chip 200 and spaced apart from each other in the first direction D1. Each of the plurality of first conductive pads 160 may penetrate the first dielectric layer 150 and may extend along the second direction D2 into the adhesive layer 300. Each of the plurality of second conductive pads 260 may penetrate the second dielectric layer 250 and may extend along the second direction D2 into the adhesive layer 300. The plurality of first conductive pads 160 and the plurality of second conductive pads 260 may correspondingly contact each other to constitute a plurality of connection pads 500. The plurality of connection pads 500 may be spaced apart from each other in the first direction D1. Each of the plurality of connection pads 500 may penetrate along the second direction D2 through the first dielectric layer 150, the adhesive layer 300, and the second dielectric layer 250, and may electrically connect the first semiconductor chip 100 and the second semiconductor chip 200 to each other.

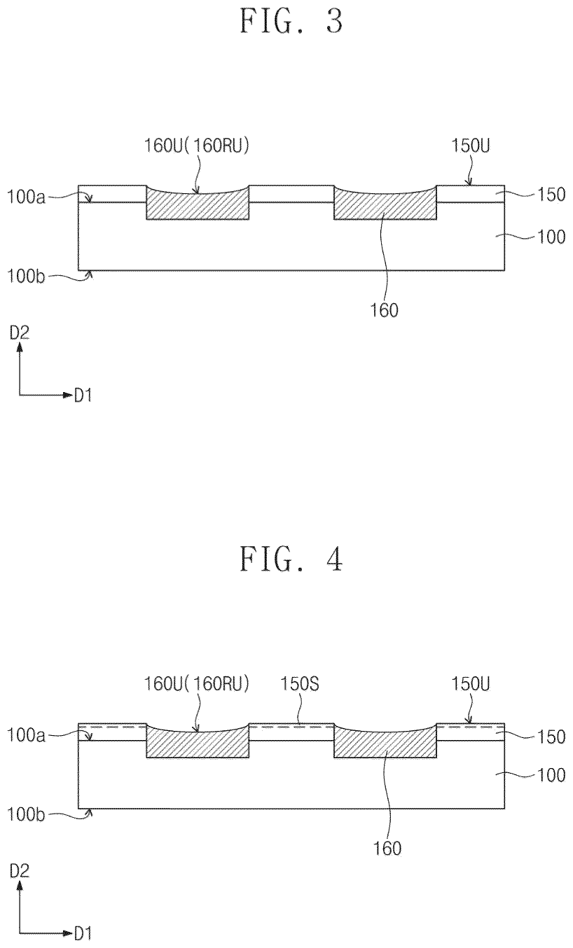

FIGS. 3 to 8 are cross-sectional views illustrating a method of fabricating a semiconductor device according to one or more embodiments. Description of aspects that are the same as or similar to those described above may be omitted.

Referring to FIG. 3, a first semiconductor chip 100 may be provided which has a first surface 100a and a second surface 100b that are opposite to each other. The first semiconductor chip 100 may include an integrated circuit therein, and for example, may be a memory chip, a logic chip, an AP chip, a SOC, etc.

First conductive pads 160 may be formed adjacent to the first surface 100a of the first semiconductor chip 100, and may be spaced apart from each other in a first direction D1 parallel to the first surface 100a. The first conductive pads 160 may be electrically connected to the integrated circuit of the first semiconductor chip 100. The first conductive pads 160 may include metal, such as copper.

A first dielectric layer 150 may be formed on the first surface 100a of the first semiconductor chip 100 and between the first conductive pads 160. The formation of the first dielectric layer 150 may include, for example, forming on the first surface 100a of the first semiconductor chip 100 the first dielectric layer 150 that covers the first conductive pads 160, and planarizing the first dielectric layer 150 until top surfaces 160U of the first conductive pads 160 are exposed. The first dielectric layer 150 may be formed by at least one of, for example, chemical vapor deposition and physical vapor deposition. For example, a chemical mechanical polishing process may be used to planarize the first dielectric layer 150. The top surfaces 160U of the first conductive pads 160 may be recessed during the planarization of the first dielectric layer 150, and each of the first conductive pads 160 may thus have a recessed top surface 160RU that is recessed toward an inside thereof. A top surface 150U of the first dielectric layer 150 may be located at a height (e.g., measured along direction D2) greater than that of the recessed top surfaces 160RU of the first conductive pads 160.

The first dielectric layer 150 may include a silicon-containing dielectric material, which silicon-containing dielectric material may include at least one of silicon oxide (SiO₂), silicon nitride (SiN), silicon oxynitride (SiON), silicon carbonitride (SiCN), and silicon carbon oxynitride (SiCON).

Referring to FIG. 4, a plasma treatment process may be performed on the top surface 150U of the first dielectric layer 150. The plasma treatment process may break at least one of Si—C bonds, Si—N bonds, and Si—O bonds in the first dielectric layer 150, and a silicon radical may thus be formed in a region 150S on the top surface 150U of the first dielectric layer 150. The silicon radical may be formed to easily achieve an interface adhesion between the first dielectric layer 150 and a first adhesive layer 170 which will be described below. According to one or more embodiments, the plasma treatment process may be omitted.

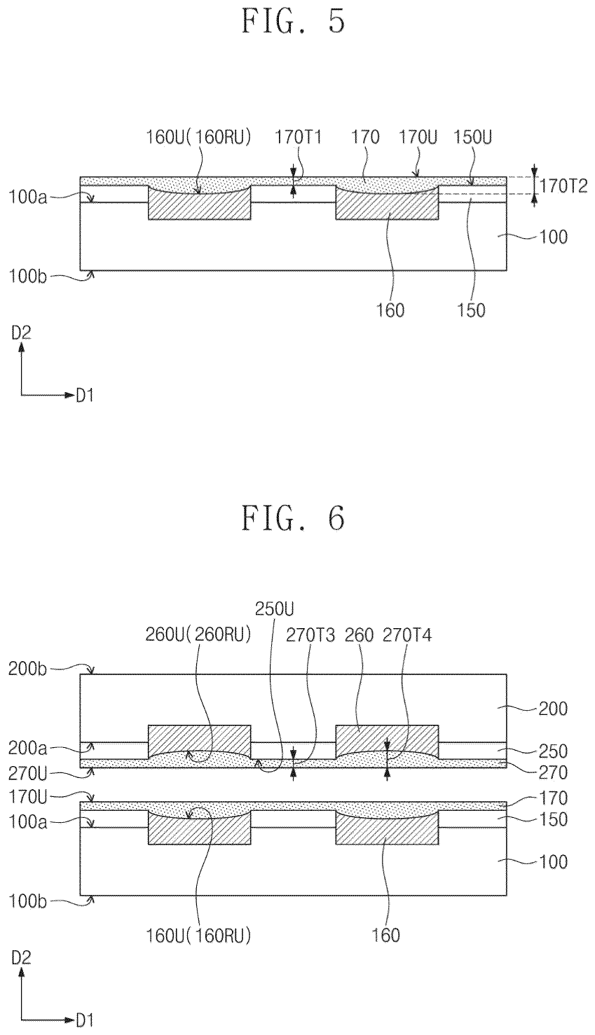

Referring to FIG. 5, a first adhesive layer 170 may be formed on the first surface 100a of the first semiconductor chip 100, and also on the first dielectric layer 150 and the first conductive pads 160. The first adhesive layer 170 may directly contact the top surface 150U of the first dielectric layer 150, and may cover the recessed top surfaces 160RU of the first conductive pads 160. As described with reference to FIG. 2, when the plasma treatment process is performed on the first dielectric layer 150, an interface adhesion between the first dielectric layer 150 and the first adhesive layer 170 may be easily achieved by the silicon radical formed in the region 150S adjacent to the top surface 150U of the first dielectric layer 150.

The first adhesive layer 170 may have a first thickness 170T1 in the second direction D2 on the first dielectric layer 150 and a second thickness 170T2 in the second direction D2 on each of the first conductive pads 160. The first thickness 170T1 may be measured in the second direction D2 from the top surface 150U of the first dielectric layer 150, and the second thickness 170T2 may be measured in the second direction D2 from the recessed top surface 160RU of each of the first conductive pads 160. The second thickness 170T2 may be greater than the first thickness 170T1. For example, the first adhesive layer 170 may be formed thicker on each of the first conductive pads 160 than on the first dielectric layer 150, and a top surface 170U of the first adhesive layer 170 may thus be located at substantially the same height. For example, the second thickness 170T2 may range from about 10 nm to about 50 nm, and the first thickness 170T1 may be less than the second thickness 170T2.

The first adhesive layer 170 may include an organic dielectric material. The first adhesive layer 170 may include, for example, at least one of epoxy, PVA, PVP, PMMA, PI, and PC. For example, the first adhesive layer 170 may include at least one polymer of PMDA-ODA, BPDA-PDA, BPA-PC, and TMC-PC. The first adhesive layer 170 may be formed by using at least one of self-assembled monolayer coating, spin coating, sol-gel coating, atomic layer deposition, chemical vapor deposition, and physical vapor deposition.

Referring to FIG. 6, a second semiconductor chip 200 may be provided which has a third surface 200a and a fourth surface 200b that are opposite to each other. The second semiconductor chip 200 may include an integrated circuit therein, and for example, may be a memory chip, a logic chip, an AP chip, a SOC, etc. According to one or more embodiments, the first semiconductor chip 100 and the second semiconductor chip 200 may be the same semiconductor chip. Alternatively, the first semiconductor chip 100 and the second semiconductor chip 200 may be different semiconductor chips from each other.

Second conductive pads 260 may be formed adjacent to the third surface 200a of the second semiconductor chip 200, and may be spaced apart from each other in the first direction D1 parallel to the third surface 200a. The second conductive pads 260 may be electrically connected to the integrated circuit of the second semiconductor chip 200. The second conductive pads 260 may include metal, such as copper. The second conductive pads 260 may include the same metal as that of the first conductive pads 160.

A second dielectric layer 250 may be formed on the third surface 200a of the second semiconductor chip 200 and between the second conductive pads 260. The second dielectric layer 250 may be formed by substantially the same method used for forming the first dielectric layer 150. While the second dielectric layer 250 is planarized, top surfaces 260U of the second conductive pads 260 may be recessed, and each of the second conductive pads 260 may thus have a recessed top surface 260RU that is recessed toward an inside thereof.

The second dielectric layer 250 may include a silicon-containing dielectric material, which silicon-containing dielectric material may include at least one of silicon oxide (SiO₂), silicon nitride (SiN), silicon oxynitride (SiON), silicon carbonitride (SiCN), and silicon carbon oxynitride (SiCON). The second dielectric layer 250 may include the same dielectric material as that of the first dielectric layer 150.

According to one or more embodiments, the plasma treatment process described with reference to FIG. 2 may also be performed on a top surface 250U of the second dielectric layer 250. In this case, the plasma treatment process may break at least one of Si—C bonds, Si—N bonds, and Si—O bonds in the second dielectric layer 250, and a silicon radical may thus be formed in a region adjacent to the top surface 250U of the second dielectric layer 250. The silicon radical may be formed to easily achieve an interface adhesion between the second dielectric layer 250 and a second adhesive layer 270 which will be described below. According to one or more embodiments, the plasma treatment process may be omitted.

A second adhesive layer 270 may be formed on the third surface 200a of the second semiconductor chip 200, and also on the second dielectric layer 250 and the second conductive pads 260. The second adhesive layer 270 may directly contact the top surface 250U of the second dielectric layer 250, and may cover the recessed top surfaces 260RU of the second conductive pads 260. When the plasma treatment process is performed on the second dielectric layer 250, an interface adhesion between the second dielectric layer 250 and the second adhesive layer 270 may be easily achieved by the silicon radical formed in the region adjacent to the top surface 250U of the second dielectric layer 250.

The second adhesive layer 270 may have a third thickness 270T3 in the second direction D2 on the second dielectric layer 250 and a fourth thickness 270T4 in the second direction D2 on each of the second conductive pads 260. The third thickness 270T3 may be measured in the second direction D2 from the top surface 250U of the second dielectric layer 250, and the fourth thickness 270T4 may be measured in the second direction D2 from the recessed top surface 260RU of each of the second conductive pads 260. The fourth thickness 270T4 may be greater than the third thickness 270T3. For example, the second adhesive layer 270 may be formed thicker on each of the second conductive pads 260 than on the second dielectric layer 250, and a top surface 270U of the second adhesive layer 270 may thus be located at substantially the same height (e.g., measured in the direction D2). For example, the fourth thickness 270T4 may range from about 10 nm to about 50 nm, and the third thickness 270T3 may be less than the fourth thickness 270T4.

The second adhesive layer 270 may include an organic dielectric material. The second adhesive layer 270 may include, for example, at least one of epoxy, PVA, PVP, PMMA, PI, and PC. For example, the second adhesive layer 270 may include at least one polymer of PMDA-ODA, BPDA-PDA, BPA-PC, and TMC-PC. The second adhesive layer 270 may include the same organic dielectric material as that of the first adhesive layer 170. The second adhesive layer 270 may be formed by substantially the same method used for forming the first adhesive layer 170.

The second semiconductor chip 200 may be provided on the first semiconductor chip 100. The third surface 200a of the second semiconductor chip 200 may face the first surface 100a of the first semiconductor chip 100. The recessed top surfaces 260RU of the second conductive pads 260 may correspondingly face the recessed top surfaces 160RU of the first conductive pads 160. The first dielectric layer 150 and the second dielectric layer 250 may be disposed between the first surface 100a of the first semiconductor chip 100 and the third surface 200a of the second semiconductor chip 200. The first adhesive layer 170 and the second adhesive layer 270 may be disposed between the first dielectric layer 150 and the second dielectric layer 250, and may extend between the first conductive pads 160 and the second conductive pads 260.

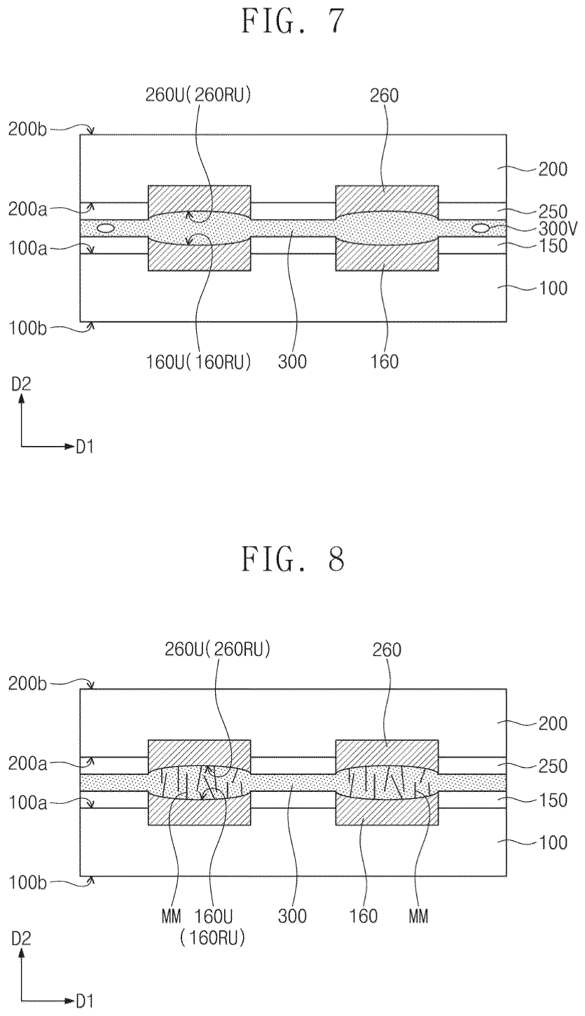

Referring to FIG. 7, the first adhesive layer 170 and the second adhesive layer 270 may be adhered to form an adhesive layer 300. The top surface 170U of the first adhesive layer 170 may directly contact the top surface 270U of the second adhesive layer 270, and the adhesive layer 300 may be formed by an interface adhesion between the first adhesive layer 170 and the second adhesive layer 270. At least one void 300V may be formed in the adhesive layer 300.

Referring to FIG. 8, a reforming process may be performed on the adhesive layer 300 and the first and second conductive pads 160 and 260. The reforming process may include providing a laser beam or a microwave to the adhesive layer 300 and the first and second conductive pads 160 and 260. During the reforming process, metal elements in the first and second conductive pads 160 and 260 may diffuse into the adhesive layer 300, and therefore, a metal diffusion layer MM may be formed in the adhesive layer 300 between the first and second conductive pads 160 and 260. During the reforming process, an organic dielectric material of the adhesive layer 300 between the first and second conductive pads 160 and 260 may diffuse into the adhesive layer 300 between the first and second dielectric layers 150 and 250, and may fill the at least one void 300V.

Referring back to FIG. 1, an annealing process may be performed on the first semiconductor chip 100 and the second semiconductor chip 200. During the annealing process, metal elements in the first and second conductive pads 160 and 260 may diffuse and thermally expand. As the metal diffusion layer MM is formed during the reforming process, and as the metal elements diffuse and thermally expand during the annealing process, each of the first and second conductive pads 160 and 260 may extend into the adhesive layer 300, and the first conductive pads 160 may correspondingly contact the second conductive pads 260. Each of the first conductive pads 160 and a corresponding second conductive pad 260 may directly contact each other to form one body and to constitute a connection pad 500. The adhesive layer 300 may have a thickness 300T in the second direction D2, and for example, the thickness 300T of the adhesive layer 300 may range from about 10 nm to about 100 nm. When the second thickness 170T2 of the first adhesive layer 170 is greater than about 50 nm, when the fourth thickness 270T4 of the second adhesive layer 270 is greater than about 50 nm, or when the thickness 300T of the adhesive layer 300 is greater than about 100 nm, it may be difficult to achieve adhesion between the first conductive pads 160 and the second conductive pads 260 during the reforming process and the annealing process. In addition, when the second thickness 170T2 of the first adhesive layer 170 is greater than about 50 nm, when the fourth thickness 270T4 of the second adhesive layer 270 is greater than about 50 nm, or when the thickness 300T of the adhesive layer 300 is greater than about 100 nm, there may be an increase in the number of the organic particles 300R in the interface region INF of the connection pad 500 as described with reference to FIGS. 2A to 2C, resulting in the connection pad 500 having an increased resistance.

In a bonding process for bonding the first semiconductor chip 100 and the second semiconductor chip 200, when the first dielectric layer 150 and the second dielectric layer 250 directly contact each other, the first and second conductive pads 160 and 260 may lead to discontinuity of the bonding between the first dielectric layer 150 and the second dielectric layer 250. In addition, a problem may occur where voids are generated at an interface between the first dielectric layer 150 and the second dielectric layer 250. Moreover, the top surfaces 160U of the first conductive pads 160 and the top surfaces 260U of the second conductive pads 260 may be outwardly exposed during the bonding process, and therefore, a metal oxide layer may be formed on the top surfaces 160U and 260U of the first and second conductive pads 160 and 260. In this case, the metal oxide layer may cause difficulty in boding the first conductive pads 160 and the second conductive pads 260. Furthermore, a chemical mechanical polishing process performed on the first and second dielectric layers 150 and 250 may allow the first conductive pads 160 and the second conductive pads 260 to have their respective recessed top surfaces 160RU and 260RU, and in this case, it may be difficult to achieve adhesion between the first conductive pads 160 and the second conductive pads 260.

According to one or more embodiments, the first adhesive layer 170 may be formed to cover the first dielectric layer 150 and the first conductive pads 160, and the second adhesive layer 270 may be formed to cover the second dielectric layer 250 and the second conductive pads 260. The adhesive layer 300 may be formed due to an interface adhesion between the first adhesive layer 170 and the second adhesive layer 270, and the first semiconductor chip 100 and the second semiconductor chip 200 may be bonded to each other through the adhesive layer 300. For example, as the first adhesive layer 170 is formed to cover the first dielectric layer 150 and the first conductive pads 160 and the second adhesive layer 270 is formed to cover the second dielectric layer 250 and the second conductive pads 260, there may be continuity of the bonding between the first adhesive layer 170 and the second adhesive layer 270, the top surfaces 160U and 260U of the first and second conductive pads 160 and 260 may be prevented from being outwardly exposed during the bonding process, and a metal oxide layer may be prevented from being formed on the top surfaces 160U and 260U of the first and second conductive pads 160 and 260.

Additionally, the reforming process may form the metal diffusion layer MM in the adhesive layer 300 between the first and second conductive pads 160 and 260, and an organic dielectric material of the adhesive layer 300 between the first and second conductive pads 160 and 260 may diffuse into the adhesive layer 300 between the first and second dielectric layers 150 and 250. As the reforming process forms the metal diffusion layer MM from the first and second conductive pads 160 and 260, even when the first conductive pads 160 and the second conductive pads 260 have their recessed top surfaces 160RU and 260RU, adhesion between the first conductive pads 160 and the second conductive pads 260 may be easily and efficiently achieved. In addition, during the reforming process, as an organic dielectric material of the adhesive layer 300 between the first and second conductive pads 160 and 260 diffuses into the adhesive layer 300 between the first and second dielectric layers 150 and 250, the void 300V formed in the adhesive layer 300 may be filled with the organic dielectric material of the adhesive layer 300. Thus, the number of the void 300V in the adhesive layer 300 may become minimized.

Accordingly, the bonding process for bonding the first semiconductor chip 100 and the second semiconductor chip 200 may be easily and efficiently performed, and the possibility of defects occurring in the bonding process may be minimized or at least reduced.

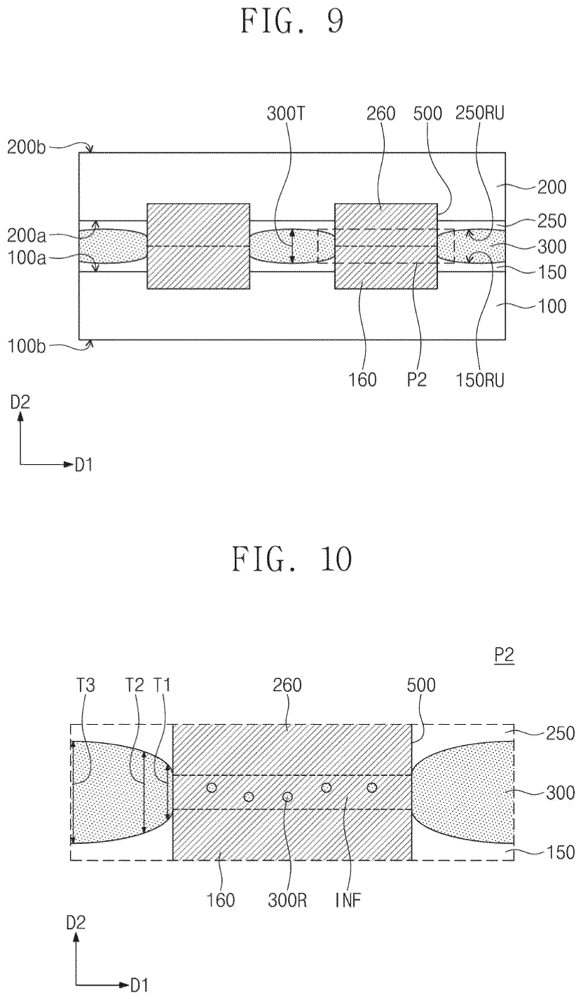

FIG. 9 is a cross-sectional view illustrating a semiconductor device according to one or more embodiments. FIG. 10 is an enlarged cross-sectional view illustrating section P2 of FIG. 9 according to one or more embodiments. Description of aspects that are the same as or similar to those described above may be omitted.

Referring to FIG. 9, the first dielectric layer 150 may have a recessed top surface 150RU that is recessed toward an inside thereof, and the second dielectric layer 250 may have a recessed top surface 250RU that is recessed toward an inside thereof. The recessed top surface 150RU of the first dielectric layer 150 may face the recessed top surface 250RU of the second dielectric layer 250. The adhesive layer 300 may fill a space between the recessed top surface 150RU of the first dielectric layer 150 and the recessed top surface 250RU of the second dielectric layer 250, and may directly contact the recessed top surface 150RU of the first dielectric layer 150 and the recessed top surface 250RU of the second dielectric layer 250. The thickness 300T in the second direction D2 of the adhesive layer 300 may increase with increasing distance from the first conductive pad 160 and the second conductive pad 260 in the first direction D1. For example, the thickness 300T of the adhesive layer 300 may increase with increasing distance from the connection pad 500. In particular, referring to FIG. 10, the adhesive layer 300 may have a first thickness T1, a second thickness T2 and a third thickness T3 along the first direction D1. The first thickness T1 at the interface between the adhesive layer 300 and the connection pad 500 may be the smallest thickness of the adhesive layer 300. The second thickness T2 may be larger than the first thickness T1, and the third thickness T3 may be larger than the second thickness T2. That is, as the distance increases from the connection pad 500, the thickness of the adhesive layer 300 may increase from T1 to T3, and then may reduce back down from T3 to T1 as the distance in the first direction D1 approaches another connection pad spaced apart from the connection pad 500 along the first direction D1.

Referring to FIGS. 9 and 10, the connection pad 500 may include an interface region INF that penetrates the adhesive layer 300, and the interface region INF of the connection pad 500 may substantially aligned with the adhesive layer 300 along the first direction D1. That is, along an axis extending in the direction D1 at the center of the adhesive layer 300, the interface region INF and the adhesive layer 300 may be substantially aligned. According to one or more embodiments, the connection pad 500 may include organic particles 300R provided in the interface region INF. The organic particles 300R may include the same material as that of the adhesive layer 300.

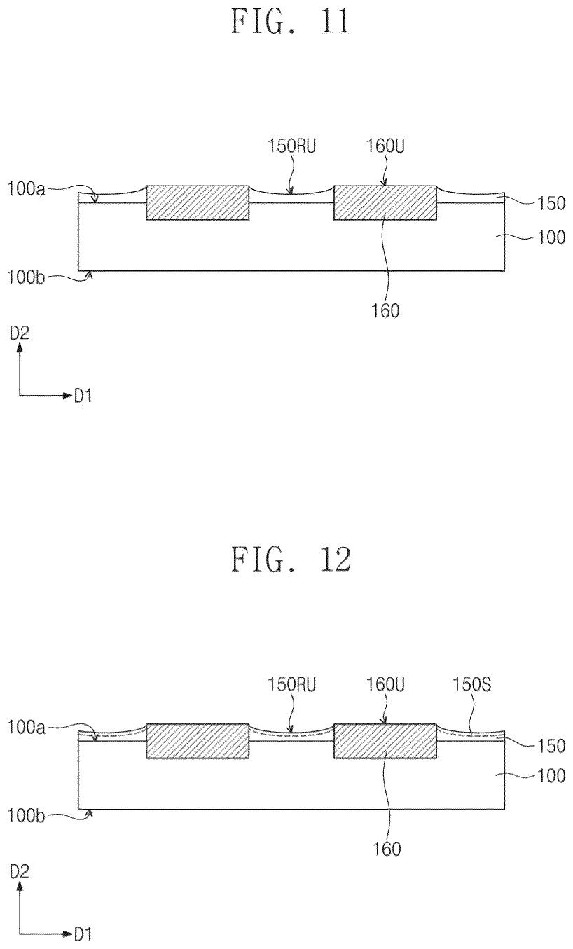

FIGS. 11 to 16 are cross-sectional views illustrating a method of fabricating a semiconductor device according to one or more embodiments. Description of aspects that are the same as or similar to those described above may be omitted.

Referring to FIG. 11, the first conductive pads 160 may be formed adjacent to the first surface 100a of the first semiconductor chip 100, and may be spaced apart from each other in the first direction D1. The first dielectric layer 150 may be formed on the first surface 100a of the first semiconductor chip 100 and between the first conductive pads 160. The formation of the first dielectric layer 150 may include, for example, forming on the first surface 100a of the first semiconductor chip 100 the first dielectric layer 150 that covers the first conductive pads 160, and planarizing the first dielectric layer 150 until top surfaces 160U of the first conductive pads 160 are exposed. For example, a chemical mechanical polishing process may be used to planarize the first dielectric layer 150. According to one or more embodiments, a top surface of the first dielectric layer 150 may be recessed during the planarization of the first dielectric layer 150, and the first dielectric layer 150 may thus have a recessed top surface 150RU that is recessed toward an inside thereof. The top surfaces 160U of the first conductive pads 160 may be located at a height (e.g., along the direction D2) greater than that of the recessed top surface 150RU of the first dielectric layer 150.

Referring to FIG. 12, the plasma treatment process may be performed on the recessed top surface 150RU of the first dielectric layer 150. The plasma treatment process may break at least one of Si—C bonds, Si—N bonds, and Si—O bonds in the first dielectric layer 150, and thus, a silicon radical may be formed in a region 150S adjacent to the recessed top surface 150RU of the first dielectric layer 150. The silicon radical may be formed to easily achieve an interface adhesion between the first dielectric layer 150 and a first adhesive layer 170 which will be described below. According to one or more embodiments, the plasma treatment process may be omitted.

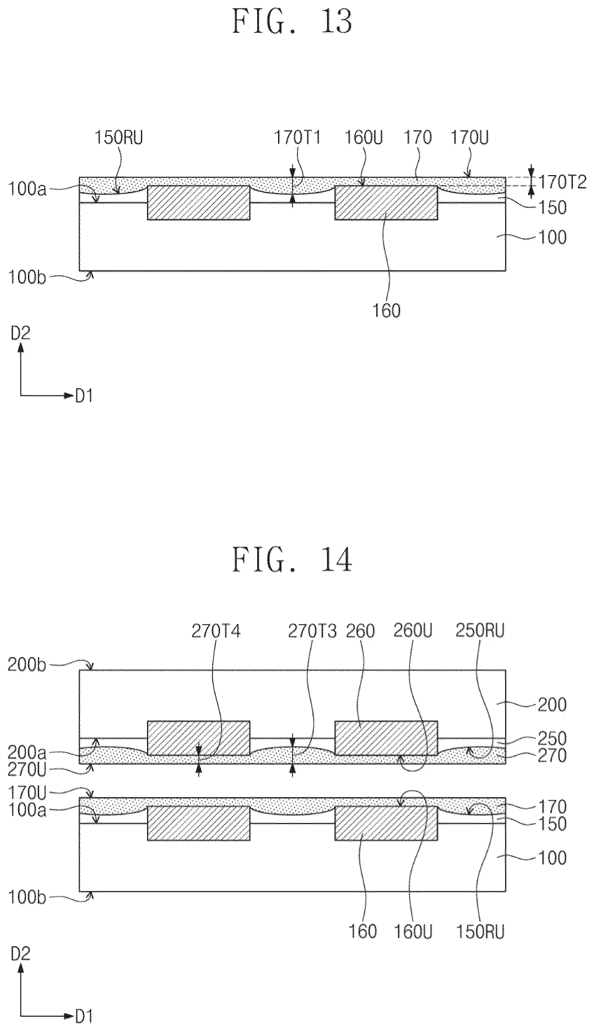

Referring to FIG. 13, the first adhesive layer 170 may be formed on the first surface 100a of the first semiconductor chip 100, and also on the first dielectric layer 150 and the first conductive pads 160. The first adhesive layer 170 may directly contact the recessed top surface 150RU of the first dielectric layer 150, and may cover the top surfaces 160U of the first conductive pads 160. As described with reference to FIG. 12, when the plasma treatment process is performed on the first dielectric layer 150, an interface adhesion between the first dielectric layer 150 and the first adhesive layer 170 may be easily achieved by the silicon radical formed in the region 150S adjacent to the recessed top surface 150RU of the first dielectric layer 150.

The first adhesive layer 170 may have a first thickness 170T1 in the second direction D2 on the first dielectric layer 150 and a second thickness 170T2 in the second direction D2 on each of the first conductive pads 160. The first thickness 170T1 may be measured in the second direction D2 from the recessed top surface 150RU of the first dielectric layer 150, and the second thickness 170T2 may be measured in the second direction D2 from the top surface 160U of each of the first conductive pads 160. According to one or more embodiments, the second thickness 170T2 may be less than the first thickness 170T1. For example, the first adhesive layer 170 may be formed thinner on each of the first conductive pads 160 than on the first dielectric layer 150, and a top surface 170U of the first adhesive layer 170 may thus be located at substantially the same height (e.g., along direction D2). For example, the second thickness 170T2 may range from about 10 nm to about 50 nm, and the first thickness 170T1 may be greater than the second thickness 170T2.

Referring to FIG. 14, the second conductive pads 260 may be formed adjacent to the third surface 200a of the second semiconductor chip 200, and may be spaced apart from each other in the first direction D1 parallel to the third surface 200a. The second dielectric layer 250 may be formed on the third surface 200a of the second semiconductor chip 200 and between the second conductive pads 260. The second dielectric layer 250 may be formed by substantially the same method used for forming the first dielectric layer 150. While the second dielectric layer 250 is planarized, a top surface of the second dielectric layer 250 may be recessed, and the second dielectric layer 250 may thus have a recessed top surface 250RU that is recessed toward an inside thereof.

According to one or more embodiments, the plasma treatment process described with reference to FIG. 12 may also be performed on the recessed top surface 250RU of the second dielectric layer 250. In this case, the plasma treatment process may break at least one of Si—C bonds, Si—N bonds, and Si—O bonds in the second dielectric layer 250, and a silicon radical may thus be formed in a region adjacent to the recessed top surface 250RU of the second dielectric layer 250. The silicon radical may be formed to easily achieve an interface adhesion between the second dielectric layer 250 and a second adhesive layer 270 which will be described below. According to one or more embodiments, the plasma treatment process may be omitted.

The second adhesive layer 270 may be formed on the third surface 200a of the second semiconductor chip 200, and also on the second dielectric layer 250 and the second conductive pads 260. The second adhesive layer 270 may directly contact the recessed top surface 250RU of the second dielectric layer 250, and may cover the top surfaces 260U of the second conductive pads 260. As described with reference to FIG. 12, when the plasma treatment process is performed on the second dielectric layer 250, an interface adhesion between the second dielectric layer 250 and the second adhesive layer 270 may be easily achieved by the silicon radical formed in the region adjacent to the recessed top surface 250RU of the second dielectric layer 250.

The second adhesive layer 270 may have a third thickness 270T3 in the second direction D2 on the second dielectric layer 250 and a fourth thickness 270T4 in the second direction D2 on each of the second conductive pads 260. The third thickness 270T3 may be measured in the second direction D2 from the recessed top surface 250RU of the second dielectric layer 250, and the fourth thickness 270T4 may be measured in the second direction D2 from the top surface 260U of each of the second conductive pads 260. According to one or more embodiments, the fourth thickness 270T4 may be less than the third thickness 270T3. For example, the second adhesive layer 270 may be formed thinner on each of the second conductive pads 260 than on the second dielectric layer 250, and thus, a top surface 270U of the second adhesive layer 270 may be located at substantially the same height (e.g., along direction D2). For example, the fourth thickness 270T4 may range from about 10 nm to about 50 nm, and the third thickness 270T3 may be greater than the fourth thickness 270T4.

The second semiconductor chip 200 may be provided on the first semiconductor chip 100. The third surface 200a of the second semiconductor chip 200 may face the first surface 100a of the first semiconductor chip 100. The top surfaces 260U of the second conductive pads 260 may correspondingly face the top surfaces 160U of the first conductive pads 160. The first dielectric layer 150 and the second dielectric layer 250 may be disposed between the first surface 100a of the first semiconductor chip 100 and the third surface 200a of the second semiconductor chip 200. The recessed top surface 250RU of the second dielectric layer 250 may face the recessed top surface 150RU of the first dielectric layer 150. The first adhesive layer 170 and the second adhesive layer 270 may be disposed between the first dielectric layer 150 and the second dielectric layer 250, and may extend between the first conductive pads 160 and the second conductive pads 260.

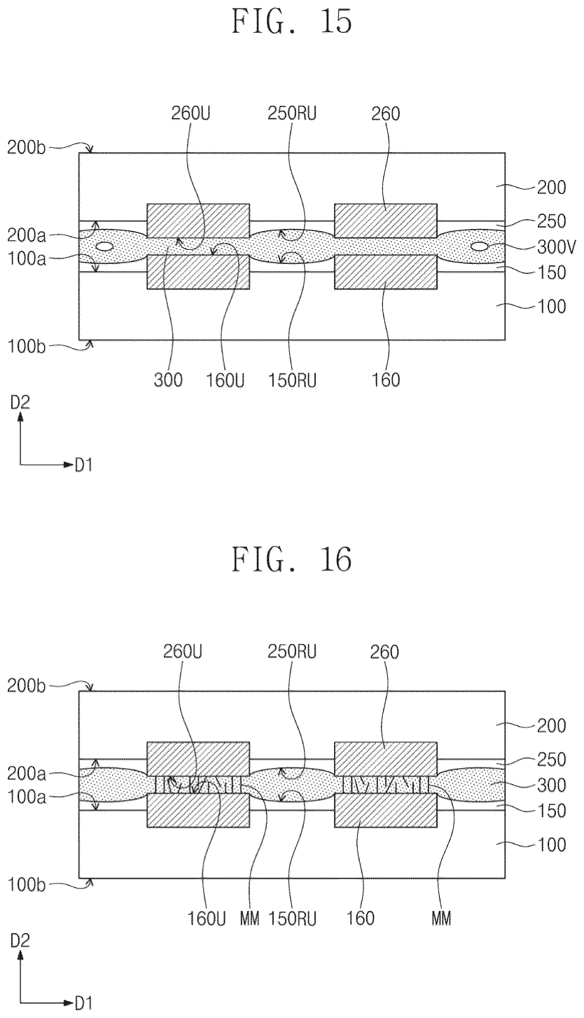

Referring to FIG. 15, the first adhesive layer 170 and the second adhesive layer 270 may be adhered to form the adhesive layer 300. The top surface 170U of the first adhesive layer 170 may directly contact the top surface 270U of the second adhesive layer 270, and the adhesive layer 300 may be formed by an interface adhesion between the first adhesive layer 170 and the second adhesive layer 270. At least one void 300V may be formed in the adhesive layer 300.

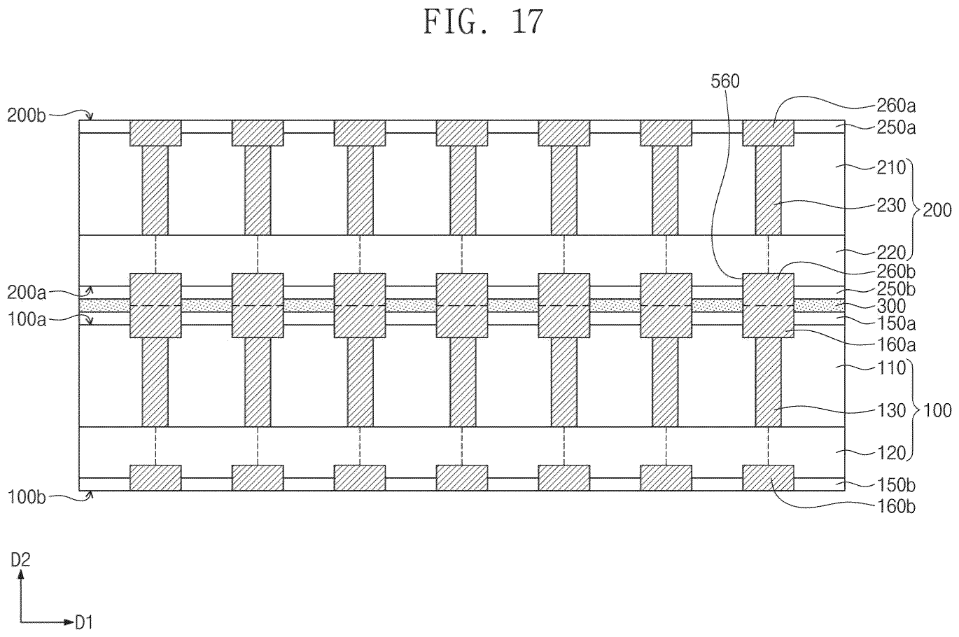

Referring to FIG. 16, the reforming process may be performed on the adhesive layer 300 and the first and second conductive pads 160 and 260. During the reforming process, metal elements in the first and second conductive pads 160 and 260 may diffuse into the adhesive layer 300, and therefore, a metal diffusion layer MM may be formed in the adhesive layer 300 between the first and second conductive pads 160 and 260. During the reforming process, an organic dielectric material of the adhesive layer 300 between the first and second conductive pads 160 and 260 may diffuse into the adhesive layer 300 between the first and second dielectric layers 150 and 250, and may fill the at least one void 300V.

Referring back to FIG. 9, the annealing process may be performed on the first semiconductor chip 100 and the second semiconductor chip 200. During the annealing process, metal elements in the first and second conductive pads 160 and 260 may diffuse and thermally expand. As the metal diffusion layer MM is formed during the reforming process, and as the metal elements diffuse and thermally expand during the annealing process, each of the first and second conductive pads 160 and 260 may extend into the adhesive layer 300, and the first conductive pads 160 may correspondingly contact the second conductive pads 260. Each of the first conductive pads 160 and its corresponding one of the second conductive pads 260 may be in direct contact with each other to form one body and to constitute a connection pad 500.

According to one or more embodiments, the second thickness 170T2 of the first adhesive layer 170 may be formed less than the first thickness 170T1 of the first adhesive layer 170, and the fourth thickness 270T4 of the second adhesive layer 270 may be formed less than the third thickness 270T3 of the second adhesive layer 270. Therefore, adhesion between the first conductive pads 160 and the second conductive pads 260 may be easily and efficiently achieved.

FIG. 17 is a cross-sectional view illustrating a semiconductor device according to one or more embodiments.

Referring to FIG. 17, a semiconductor device may include a first semiconductor chip 100 and a second semiconductor chip 200 stacked on the first semiconductor chip 100.

The first semiconductor chip 100 may have a first surface 100a and a second surface 100b that are opposite to each other. The first semiconductor chip 100 may include a first semiconductor substrate 110 adjacent to the first surface 100a, a first circuit layer 120 adjacent to the second surface 100b, and first through electrodes 130 that penetrate the first semiconductor substrate 110 and have an electrical connection with the first circuit layer 120. The first through electrodes 130 may be spaced apart horizontally (e.g., in the first direction D1) from each other in the first semiconductor substrate 110. Each of the first through electrodes 130 may penetrate the first semiconductor substrate 110 to come into electrical connection with the first circuit layer 120. The first semiconductor substrate 110 may be a silicon substrate, a germanium substrate, a silicon-germanium substrate, or a silicon-on-insulator (SOI) substrate. The first circuit layer 120 may include an integrated circuit. The first through electrodes 130 may include metal (e.g., copper (Cu)). The first semiconductor chip 100 may be, for example, a memory chip, a logic chip, an application processor (AP) chip, or a system-on-chip (SOC).

The semiconductor device may further include first upper conductive pads 160a disposed adjacent to the first surface 100a of the first semiconductor chip 100, a first upper dielectric layer 150a disposed adjacent to the first surface 100a of the first semiconductor chip 100 and interposed between the first upper conductive pads 160a, first lower conductive pads 160b disposed adjacent to the second surface 100b of the first semiconductor chip 100, and a first lower dielectric layer 150b disposed adjacent to the second surface 100b of the first semiconductor chip 100 and interposed between the first lower conductive pads 160b.

The first upper conductive pads 160a may be spaced apart from each other in the first direction D1, and may be correspondingly connected to the first through electrodes 130. The first upper conductive pads 160a may be electrically connected through the first through electrodes 130 to the first circuit layer 120. The first lower conductive pads 160b may be spaced apart from each other in the first direction D1, and may be electrically connected to the first circuit layer 120. The first upper conductive pads 160a and the first lower conductive pads 160b may be substantially the same as the first conductive pads 160 described with reference to FIGS. 1 to 16, and the first upper dielectric layer 150a and the first lower dielectric layer 150b may be substantially the same as the first dielectric layer 150 described with reference to FIGS. 1 to 16.

The second semiconductor chip 200 may have a third surface 200a and a fourth surface 200b that are opposite to each other. The second semiconductor chip 200 may include a second semiconductor substrate 210 adjacent to the fourth surface 200b, a second circuit layer 220 adjacent to the third surface 200a, and second through electrodes 230 that penetrate the second semiconductor substrate 210 and have an electrical connection with the second circuit layer 220. The second through electrodes 230 may be spaced apart horizontally (e.g., in the first direction D1) from each other in the second semiconductor substrate 210. Each of the second through electrodes 230 may penetrate the second semiconductor substrate 210 to come into electrical connection with the second circuit layer 220. The second semiconductor substrate 210 may be a silicon substrate, a germanium substrate, a silicon-germanium substrate, or a silicon-on-insulator (SOI) substrate. The second circuit layer 220 may include an integrated circuit. The second through electrodes 230 may include metal (e.g., copper (Cu)). The second semiconductor chip 200 may be, for example, a memory chip, a logic chip, an AP chip, a SOC, etc.

The semiconductor device may further include second upper conductive pads 260a disposed adjacent to the fourth surface 200b of the second semiconductor chip 200, a second upper dielectric layer 250a disposed adjacent to the fourth surface 200b of the second semiconductor chip 200 and interposed between the second upper conductive pads 260a, second lower conductive pads 260b disposed adjacent to the third surface 200a of the second semiconductor chip 200, and a second lower dielectric layer 250b disposed adjacent to the third surface 200a of the second semiconductor chip 200 and interposed between the second lower conductive pads 260b.

The second upper conductive pads 260a may be spaced apart from each other in the first direction D1, and may be correspondingly connected to the second through electrodes 230. The second upper conductive pads 260a may be electrically connected through the second through electrodes 230 to the second circuit layer 220. The second lower conductive pads 260b may be spaced apart from each other in the first direction D1, and may be electrically connected to the second circuit layer 220. The second upper conductive pads 260a and the second lower conductive pads 260b may be substantially the same as the second conductive pads 260 described with reference to FIGS. 1 to 16, and the second upper dielectric layer 250a and the second lower dielectric layer 250b may be substantially the same as the second dielectric layer 250 described with reference to FIGS. 1 to 16.

The third surface 200a of the second semiconductor chip 200 may face the first surface 100a of the first semiconductor chip 100. The first upper dielectric layer 150a and the second lower dielectric layer 250b may be interposed between the first surface 100a of the first semiconductor chip 100 and the third surface 200a of the second semiconductor chip 200. The semiconductor device may further include an adhesive layer 300 interposed between the first upper dielectric layer 150a and the second lower dielectric layer 250b. The adhesive layer 300 may be substantially the same as the adhesive layer 300 described with reference to FIGS. 1 to 16.

The first upper conductive pads 160a may correspondingly face and directly contact the second lower conductive pads 260b. Each of the first upper conductive pads 160a and its corresponding one of the second lower conductive pads 260b may directly contact each other to constitute a connection pad 560. The connection pad 560 may be substantially the same as the connection pad 500 described with reference to FIGS. 1 to 16. A plurality of connection pads 560 may be provided, and the plurality of connection pads 560 may be spaced apart from each other in the first direction D1 between the first semiconductor chip 100 and the second semiconductor chip 200. Each of the plurality of connection pads 560 may penetrate the first upper dielectric layer 150a, the adhesive layer 300, and the second lower dielectric layer 250b, and may electrically connect the first semiconductor chip 100 and the second semiconductor chip 200 to each other.

The first semiconductor chip 100 and the second semiconductor chip 200 may be the same semiconductor chip or different semiconductor chips.

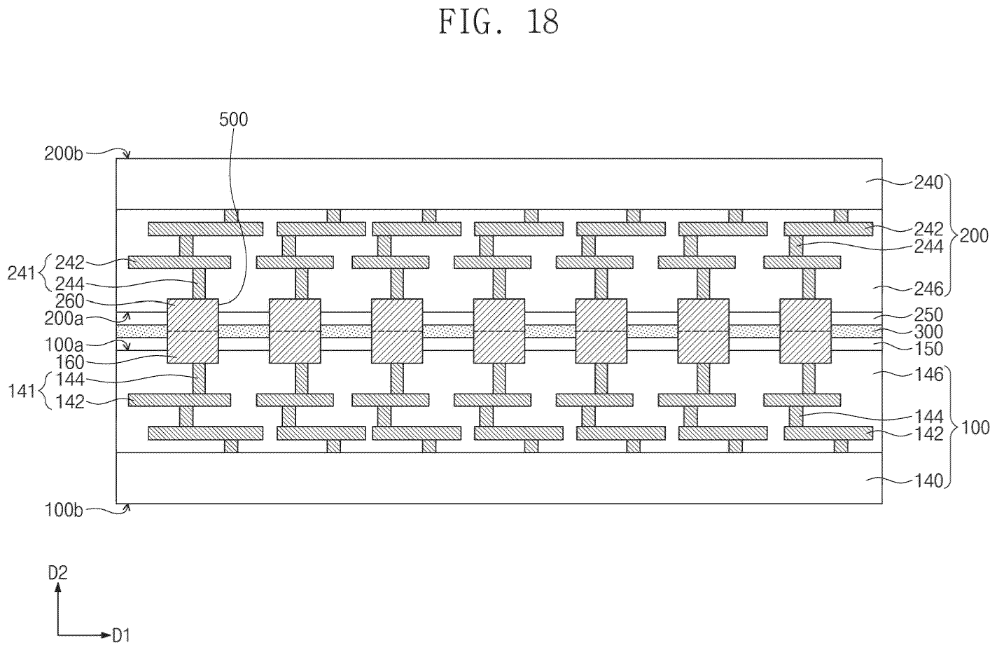

FIG. 18 is a cross-sectional view illustrating a semiconductor device according to one or more embodiments.

Referring to FIG. 18, a semiconductor device may include a first semiconductor chip 100 and a second semiconductor chip 200 stacked on the first semiconductor chip 100.

The first semiconductor chip 100 may have a first surface 100a and a second surface 100b that are opposite to each other. The first semiconductor chip 100 may include a first substrate 140, first wiring patterns 141 disposed on the first substrate 140, and a first interlayer dielectric layer 146 disposed on the first substrate 140 and covering the first wiring patterns 141. The first interlayer dielectric layer 146 may be adjacent to the first surface 100a of the first semiconductor chip 100, and the first substrate 140 may be adjacent to the second surface 100b of the first semiconductor chip 100.

The first substrate 140 may include a first semiconductor substrate and an integrated circuit on the first semiconductor substrate. The first semiconductor substrate may include, for example, a silicon substrate, a germanium substrate, a silicon-germanium substrate, or a silicon-on-insulator (SOI) substrate. The first wiring patterns 141 may include first wiring lines 142 and first wiring contacts 144. The first wiring lines 142 may be spaced apart vertically (e.g., in the second direction D2) from the first substrate 140, and may be electrically connected to the integrated circuit of the first substrate 140 through corresponding ones of the first wiring contacts 144. The first wiring lines 142 may be spaced apart vertically (e.g., in the second direction D2) from each other, and may be electrically connected to each other through corresponding ones of the first wiring contacts 144. The first wiring lines 142 and the first wiring contacts 144 may include a conductive material (e.g., metal). The first wiring lines 142 and the first wiring contacts 144 may be disposed in the first interlayer dielectric layer 146. The first interlayer dielectric layer 146 may include, for example, one or more of silicon oxide, silicon nitride, and silicon oxynitride.

The first semiconductor chip 100 may be, for example, a memory chip, a logic chip, an AP chip, a SOC, etc.

The semiconductor device may include first conductive pads 160 disposed adjacent to the first surface 100a of the first semiconductor chip 100, and a first dielectric layer 150 disposed adjacent to the first surface 100a of the first semiconductor chip 100 and interposed between the first conductive pads 160. The first dielectric layer 150 may be disposed on the first interlayer dielectric layer 146. The first conductive pads 160 may be disposed on the first interlayer dielectric layer 146, and may be spaced apart from each other in the first direction D1. The first wiring patterns 141 and the first interlayer dielectric layer 146 may be disposed between the first substrate 140 and the first dielectric layer 150 and between the first substrate 140 and the first conductive pads 160. Each of the first conductive pads 160 may penetrate the first dielectric layer 150 and may extend into the first interlayer dielectric layer 146. The first conductive pads 160 may be electrically connected through corresponding ones of the first wiring contacts 144 to corresponding ones of the first wiring lines 142. The first conductive pads 160 may be electrically connected through the first wiring contacts 144 and the first wiring lines 142 to the integrated circuit of the first substrate 140. The first conductive pads 160 and the first dielectric layer 150 may be substantially the same as the first conductive pads 160 and the first dielectric layer 150 described with reference to FIGS. 1 to 16.

The second semiconductor chip 200 may have a third surface 200a and a fourth surface 200b that are opposite to each other. The second semiconductor chip 200 may include a second substrate 240, second wiring patterns 241 disposed on the second substrate 240, and a second interlayer dielectric layer 246 disposed on the second substrate 240 and covering the second wiring patterns 241. The second interlayer dielectric layer 246 may be adjacent to the third surface 200a of the second semiconductor chip 200, and the second substrate 240 may be adjacent to the fourth surface 200b of the second semiconductor chip 200.

The second substrate 240 may include a second semiconductor substrate and an integrated circuit on the second semiconductor substrate. The second semiconductor substrate may include, for example, a silicon substrate, a germanium substrate, a silicon-germanium substrate, or a silicon-on-insulator (SOI) substrate. The second wiring patterns 241 may include second wiring lines 242 and second wiring contacts 244. The second wiring lines 242 may be spaced apart vertically (e.g., in the second direction D2) from the second substrate 240, and may be electrically connected to the integrated circuit of the second substrate 240 through corresponding ones of the second wiring contacts 244. The second wiring lines 242 may be spaced apart vertically (e.g., in the second direction D2) from each other, and may be electrically connected to each other through corresponding ones of the second wiring contacts 244. The second wiring lines 242 and the second wiring contacts 244 may include a conductive material (e.g., metal). The second wiring lines 242 and the second wiring contacts 244 may be disposed in the second interlayer dielectric layer 246. The second interlayer dielectric layer 246 may include, for example, one or more of silicon oxide, silicon nitride, and silicon oxynitride.

The second semiconductor chip 200 may be, for example, a memory chip, a logic chip, an AP chip, a SOC, etc.

The semiconductor device may include second conductive pads 260 disposed adjacent to the third surface 200a of the second semiconductor chip 200, and a second dielectric layer 250 disposed adjacent to the third surface 200a of the second semiconductor chip 200 and interposed between the second conductive pads 260. The second dielectric layer 250 may be disposed on the second interlayer dielectric layer 246. The second conductive pads 260 may be disposed on the second interlayer dielectric layer 246, and may be spaced apart from each other in the first direction D1. The second wiring patterns 241 and the second interlayer dielectric layer 246 may be disposed between the second substrate 240 and the second dielectric layer 250 and between the second substrate 240 and the second conductive pads 260. Each of the second conductive pads 260 may penetrate the second dielectric layer 250 and may extend into the second interlayer dielectric layer 246. The second conductive pads 260 may be electrically connected through corresponding ones of the second wiring contacts 244 to corresponding ones of the second wiring lines 242. The second conductive pads 260 may be electrically connected through the second wiring contacts 244 and the second wiring lines 242 to the integrated circuit of the second substrate 240. The second conductive pads 260 and the second dielectric layer 250 may be substantially the same as the second conductive pads 260 and the second dielectric layer 250 described with reference to FIGS. 1 to 16.

The third surface 200a of the second semiconductor chip 200 may face the first surface 100a of the first semiconductor chip 100. The first dielectric layer 150 and the second dielectric layer 250 may be interposed between the first surface 100a of the first semiconductor chip 100 and the third surface 200a of the second semiconductor chip 200. The semiconductor device may further include and adhesive layer 300 interposed between the first dielectric layer 150 and the second dielectric layer 250. The adhesive layer 300 may be substantially the same as the adhesive layer 300 described with reference to FIGS. 1 to 16.

The first conductive pads 160 may correspondingly face and directly contact the second conductive pads 260. Each of the first conductive pads 160 and its corresponding one of the second conductive pads 260 may directly contact each other to constitute a connection pad 500. The connection pad 500 may be substantially the same as the connection pad 500 described with reference to FIGS. 1 to 16. A plurality of connection pads 500 may be provided, and the plurality of connection pads 500 may be spaced apart from each other in the first direction D1 between the first semiconductor chip 100 and the second semiconductor chip 200. Each of the plurality of connection pads 500 may penetrate the first dielectric layer 150, the adhesive layer 300, and the second dielectric layer 250, and may electrically connect the first semiconductor chip 100 and the second semiconductor chip 200 to each other.

The first semiconductor chip 100 and the second semiconductor chip 200 may be the same semiconductor chip or different semiconductor chips. According to one or more embodiments, the first substrate 140 of the first semiconductor chip 100 may include a memory circuit, and the second substrate 240 of the second semiconductor chip 200 may include a peripheral circuit for driving the memory circuit.

According to one or more embodiments, a first adhesive layer may be formed to cover a first dielectric layer and first conductive pads, and a second adhesive layer may be formed to cover a second dielectric layer and second conductive pads. An adhesive layer may be formed by an interface adhesion between the first adhesive layer and the second adhesive layer, and a first semiconductor chip and a second semiconductor chip may be bonded to each other through the adhesive layer. For example, the first adhesive layer covering the first dielectric layer and the first conductive pads may be continuously bonded to the second adhesive layer covering the second dielectric layer and the second conductive pads, thereby forming the adhesive layer to provide continuity of the bonding between the first adhesive layer and the second adhesive layer.

In addition, as the first adhesive layer is formed to cover the first conductive pads and the second adhesive layer is formed to cover the second conductive pads, top surfaces of the first and second conductive pads may be prevented from being outwardly exposed during a bonding process of the first semiconductor chip and the second semiconductor chip, and thus a metal oxide layer may be prevented from being formed on the top surfaces of the first and second conductive pads. As a result, adhesion between the first conductive pads and the second conductive pads during the bonding process may be easily and efficiently achieved.

Moreover, a reforming process may lead to the formation of a metal diffusion layer from the first and second conductive pads, and therefore, an adhesion may be easily established between the first conductive pads and the second conductive pads. As the reforming process forms the metal diffusion layer from the first and second conductive pads, even when the first conductive pads and the second conductive pads have their recessed top surfaces, adhesion between the first conductive pads and the second conductive pads may be easily and efficiently achieved. In addition, during the reforming process, an organic dielectric material of the adhesive layer between the first and second conductive pads may diffuse into the adhesive layer between the first and second dielectric layers, and a void formed in the adhesive layer may be filled with the organic dielectric material of the adhesive layer. Thus, the number of the void in the adhesive layer may become minimized.

Accordingly, one or more example embodiments may provide a semiconductor device and a fabrication method that is capable of easily achieving adhesion between a plurality of semiconductor chips and minimizing defects possibly occurring the bonding process of the plurality of semiconductor chips.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device, comprising:
a first semiconductor chip having a first surface and a second surface that is opposite to the first surface;
a second semiconductor chip having a third surface facing the first surface and a fourth surface that is opposite to the third surface;
a first dielectric layer on the first surface of the first semiconductor chip;
a second dielectric layer on the third surface of the second semiconductor chip;
a connection pad comprising a first conductive pad penetrating the first dielectric layer and a second conductive pad penetrating the second dielectric layer; and
an adhesive layer between the first dielectric layer and the second dielectric layer,
wherein the adhesive layer comprises an organic dielectric material,
wherein the first conductive pad and the second conductive pad extend into the adhesive layer, and
wherein the first conductive pad directly contacts the second conductive pad.

2. The semiconductor device of claim 1, wherein the first dielectric layer and the second dielectric layer comprise a silicon-containing dielectric material.

3. The semiconductor device of claim 1, wherein the adhesive layer comprises at least one of epoxy, polyvinyl alcohol (PVA), polyvinyl phenol (PVP), polymethylmethacrylate (PMMA), polyimide (PI), and polycarbonate (PC).

4. The semiconductor device of claim 1, wherein the first conductive pad and the second conductive pad comprise metal.

5. The semiconductor device of claim 1, wherein the connection pad comprises an interface region penetrating the adhesive layer, and
wherein the connection pad comprises organic particles in the interface region.

6. The semiconductor device of claim 5, wherein the organic particles comprise a material that is the same as a material of the adhesive layer.

7. The semiconductor device of claim 1, wherein, in a first direction perpendicular to the first surface of the first semiconductor chip, the adhesive layer has a thickness that increases as a distance of the adhesive layer from the first conductive pad and the second conductive pad increases in a second direction perpendicular to the first direction.

8. The semiconductor device of claim 1, wherein the first semiconductor chip comprises:
a first circuit layer;
a first semiconductor substrate between the first circuit layer and the first surface; and
a first through electrode penetrating the first semiconductor substrate and connecting the first conductive pad and the first circuit layer.

9. The semiconductor device of claim 8, wherein the second semiconductor chip comprises:
a second circuit layer;
a second semiconductor substrate between the second circuit layer and the fourth surface; and
a second through electrode penetrating the second semiconductor substrate and connected to the second circuit layer, and
wherein the second conductive pad is connected to the second circuit layer.

10. The semiconductor device of claim 1, wherein the first semiconductor chip comprises:
a first substrate;
a plurality of first wiring patterns between the first substrate and the first conductive pad; and
a first interlayer dielectric layer between the first substrate and the first conductive pad, the first interlayer dielectric layer covering the plurality of first wiring patterns, and
wherein the first conductive pad is electrically connected to a corresponding first wiring pattern of the plurality of first wiring patterns.

11. The semiconductor device of claim 10, wherein the second semiconductor chip comprises:
a second substrate;
a plurality of second wiring patterns between the second substrate and the second conductive pad; and
a second interlayer dielectric layer between the second substrate and the second conductive pad, the second interlayer dielectric layer covering the plurality of second wiring patterns,
wherein the second conductive pad is connected to a corresponding second wiring pattern of the plurality of second wiring patterns.

12. A semiconductor device, comprising:
a first semiconductor chip having a first surface and a second surface that is opposite to the first surface;
a second semiconductor chip having a third surface facing the first surface and a fourth surface that is opposite to the third surface;
a connection pad comprising a first conductive pad and a second conductive pad; and
an adhesive layer between the first surface of the first semiconductor chip and the third surface of the second semiconductor chip,
wherein the adhesive layer comprises an organic dielectric material,
wherein the first conductive pad extends from the first surface into the adhesive layer,
wherein the second conductive pad extends from the third surface into the adhesive layer, and
wherein the first conductive pad contacts the second conductive pad.

13. The semiconductor device of claim 12, wherein the first conductive pad and the second conductive pad comprise metal.

14. The semiconductor device of claim 13, wherein the adhesive layer comprises at least one of epoxy, polyvinyl alcohol (PVA), polyvinyl phenol (PVP), polymethylmethacrylate (PMMA), polyimide (PI), and polycarbonate (PC).

15. The semiconductor device of claim 13, wherein the connection pad further comprises:
an interface region penetrating the adhesive layer; and
organic particles in the interface region.

16. The semiconductor device of claim 15, wherein the organic particles comprise a material that is the same as a material of the adhesive layer.

17. The semiconductor device of claim 12, wherein, in a first direction perpendicular to the first surface of the first semiconductor chip, the adhesive layer has a thickness that increases as a distance of the adhesive layer from the first conductive pad and the second conductive pad increases in a second direction perpendicular to the first direction.

18. A semiconductor device, comprising:
a first semiconductor chip having a first surface and a second surface that is opposite to the first surface;
a second semiconductor chip having a third surface facing the first surface and a fourth surface that is opposite to the third surface;
a plurality of connection pads spaced apart from each other in a first direction parallel to the first surface, each of the plurality of connection pads comprising a first conductive pad and a second conductive pad directly contacting the first conductive pad;
a first dielectric layer on the first surface and between the first conductive pads of the plurality of connection pads;
a second dielectric layer on the third surface and between the second conductive pads of the plurality of connection pads; and
an adhesive layer between the first dielectric layer and the second dielectric layer,
wherein the adhesive layer comprises an organic dielectric material, and
wherein the first conductive pads and the second conductive pads of the plurality of connection pads extend into the adhesive layer.

19. The semiconductor device of claim 18, wherein the adhesive layer directly contacts the first dielectric layer and the second dielectric layer.

20. The semiconductor device of claim 19, wherein,
each of the plurality of connection pads comprises an interface region that is substantially aligned with the adhesive layer in the first direction,
wherein at least one connection pad of the plurality of connection pads comprises organic particles in the interface region, and
wherein the organic particles comprise a material that is the same as a material of the adhesive layer.
